(19) United States
(12) Patent Application Publication
(10) Pub. No.: US 2026/0271405 A1
(43) Pub. Date: Sep. 10, 2026

(54) SEMICONDUCTOR INTEGRATED CIRCUIT DEVICE

(71) Applicant: Socionext Inc., Kanagawa (JP)

(72) Inventor: Masatomo ICHIOKA, Yokohama-shi (JP)

(21) Appl. No.: 19/639,698

(22) Filed: Apr. 6, 2026

Related U.S. Application Data
(63) Continuation of application No. PCT/JP2023/039891, filed on Nov. 6, 2023.

(51) Int. Cl. H10D 89/10; H10W 20/43

(52) U.S. Cl. CPC H10D 89/10; H10W 20/43

(57) ABSTRACT

A semiconductor integrated circuit device includes transistors cross-coupled between differential output terminals. Dummy transistors are formed at positions different from the transistors in the depth direction and overlapping these transistors in planar view. Active regions of the transistors are configured line-symmetrically or point-symmetrically, and active regions of the dummy transistors are also configured line-symmetrically or point-symmetrically. In the dummy transistors, the electrical connection states of sources/drains located at symmetric positions are the same.

### CROSS-REFERENCE TO RELATED APPLICATIONS

This is a continuation of International Application No. PCT/JP2023/039891 filed on Nov. 6, 2023. The entire disclosure of this application is incorporated by reference herein.

### BACKGROUND

The present disclosure relates to a layout structure of a semiconductor integrated circuit device.

For higher integration of a semiconductor integrated circuit device, there is available a complementary field effect transistor (CFET) technique in which transistors are stacked one upon another in the direction normal to the substrate. The direction normal to the substrate is herein called the depth direction. Moreover, for higher integration of a semiconductor integrated circuit device, there is proposed a technique in which interconnects are provided right under transistors and connected to source/drain regions of the transistors.

US Patent Application Publication No. 2022/0344255 (Patent Document 1) discloses structure of a standard cell using the CFET technique and interconnects right under transistors.

Also, an analog circuit handling an analog signal is one of basic circuits constituting a semiconductor integrated circuit. The analog circuit often handles differential signals from the viewpoint of high-speed, noise-resistance, and other properties. However, depending on the conditions such as variations in manufacture, the temperature, and the voltage, the balance between differential signals may be lost, causing a difference in signal transition timing between the differential signals.

US Patent Application Publication No. 2003/0139164 (Patent Document 2) discloses circuit configuration in which a cross-coupled circuit is inserted between differential output terminals for synchronizing the signal transition timings of differential signals.

In Patent Document 1, however, no study has been made on applying the layout structure using CFETs to the circuit configuration in which a cross-coupled circuit is inserted between differential output terminals.

An objective of the present disclosure is providing a layout structure using CFETs for a circuit configuration in which a cross-coupled circuit is inserted between differential output terminals.

### SUMMARY

According to the first mode of the disclosure, a semiconductor integrated circuit device includes: a first transistor of a first conductivity type having a first active region forming a channel, source, and drain of a transistor; a second transistor of the first conductivity type located at a same position as the first transistor in a depth direction and having a second active region forming a channel, source, and drain of a transistor; a first dummy transistor of a second conductivity type located at a different position from the first transistor in the depth direction, placed at a position overlapping the first transistor in planar view, and having a third active region forming a channel, source, and drain of a transistor; and a second dummy transistor of the second conductivity type located at a same position as the first dummy transistor in the depth direction, placed at a position overlapping the second transistor in planar view, and having a fourth active region forming a channel, source, and drain of a transistor, wherein the first transistor has a source connected to a power supply, a drain connected to a first node that is one of differential output terminals, and a gate connected to a second node that is the other of the differential output terminals, the second transistor has a source connected to the power supply, a drain connected to the second node, and a gate connected to the first node, the first dummy transistor has a gate connected to the second node, the second dummy transistor has a gate connected to the first node, the first active region and the second active region are configured line-symmetrically with respect to a predetermined straight line, or point-symmetrically with respect to a predetermined point, in planar view, the third active region and the fourth active region are configured line-symmetrically with respect to the predetermined straight line, or point-symmetrically with respect to the predetermined point, in planar view, and in the third and fourth active regions, electrical connection states of sources and drains located at symmetric positions with respect to the predetermined straight line, or located at symmetric positions with respect to the predetermined point, are the same. According to the above mode, the semiconductor integrated circuit device includes first and second transistors cross-coupled between differential output terminals. The first and second transistors constitute an adjusting circuit configured to adjust the signal transition timings of the differential output signals. First and second dummy transistors are formed at positions different from the first and second transistors in the depth direction and overlapping these transistors in planar view. First and second active regions of the first and second transistors are configured line-symmetrically or point-symmetrically to each other in planar view. Third and fourth active regions of the first and second dummy transistors are also configured line-symmetrically or point-symmetrically to each other in planar view. In the third and fourth active regions of the first and second dummy transistors, the electrical connection states of the sources and the drains located at symmetric positions are the same. Since this curbs unevenness in the characteristics of the first and second transistors constituting the adjusting circuit, a difference in signal transition timing between the differential output signals can be curbed. According to the present disclosure, a layout structure using CFETs is implemented for a circuit configuration in which a cross-coupled circuit is inserted between differential output terminals.

### BRIEF DESCRIPTION OF THE DRAWINGS

FIG. 1 shows a circuit configuration example of a differential output circuit according to the first embodiment.

FIG. 2 is a signal waveform diagram showing an operation example of the differential output circuit shown in FIG. 1.

FIG. 3 is a plan view showing a layout structure example of the differential output circuit shown in FIG. 1, illustrating the structure of an upper part.

FIG. 4 is a plan view showing the layout structure example of the differential output circuit shown in FIG. 1, illustrating the structure of a lower part.

FIGS. 5A and 5B are cross-sectional views of the layout structure shown in FIGS. 3 and 4.

FIGS. 6A and 6B are cross-sectional views of the layout structure shown in FIGS. 3 and 4.

FIG. 7 shows an alteration of the layout structure of FIG. 4.

FIG. 8 is a plan view showing an alteration of the layout structure example of the differential output circuit shown in FIG. 1, illustrating the structure of an upper part.

FIG. 9 is a plan view showing the alteration of the layout structure example of the differential output circuit shown in FIG. 1, illustrating the structure of a lower part.

FIG. 10 shows a circuit configuration example of a differential output circuit according to the second embodiment.

FIG. 11 is a signal waveform diagram showing an operation example of the differential output circuit shown in FIG. 10.

FIG. 12 is a plan view showing a layout structure example of the differential output circuit shown in FIG. 10, illustrating the structure of an upper part.

FIG. 13 is a plan view showing the layout structure example of the differential output circuit shown in FIG. 10, illustrating the structure of a lower part.

FIG. 14 shows a circuit application example including the differential output circuit shown in FIG. 1.

FIG. 15 shows another circuit application example including the differential output circuit shown in FIG. 1.

### DETAILED DESCRIPTION

Embodiments of the present disclosure will be described hereinafter with reference to the accompanying drawings. In the following embodiments, the semiconductor integrated circuit device includes nanosheet field effect transistors (FETs). According to the present disclosure, however, transistors included in the semiconductor integrated circuit device are not limited to nanosheet FETs.

As used herein, “VDD” and “VSS” refer to power supply voltages or power supplies themselves. Also, “IN”, “INX”, “XA”, and “XB” refer to signals or signal terminals, and “L” and “H” refer to the low and high levels of a signal voltage. As used herein, an expression indicating that sizes such as widths are identical, like the “same wiring width,” is to be understood as including a range of variations in manufacture.

### First Embodiment

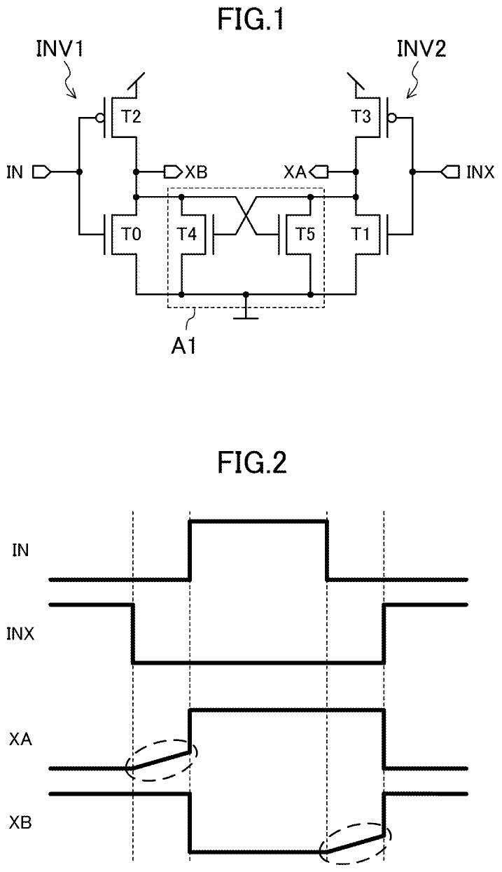

FIG. 1 is a circuit diagram showing a circuit configuration example of a differential output circuit according to the first embodiment. The differential output circuit is a type of analog circuit. The differential output circuit of FIG. 1 receives differential input signals IN and INX as inputs, and outputs differential output signals XA and XB. The differential output circuit of FIG. 1 has a circuit (adjusting circuit A1) that adjusts the signal transition timings of the differential output signals XA and XB.

The differential output circuit of FIG. 1 includes n-type transistors T0, T1, T4, and T5 and p-type transistors T2 and T3. The transistors T0 and T2 constitute an inverter INV1, and the transistors T1 and T3 constitute an inverter INV2. The inverter INV1 has an input connected to a differential input terminal IN and an output connected to a differential output terminal XB. The inverter INV2 has an input connected to a differential input terminal INX and an output connected to a differential output terminal XA.

The transistors T4 and T5 are cross-coupled between the differential output terminals XA and XB and constitute the adjusting circuit A1. That is, the transistor T4 has a drain connected to the differential output terminal XB, a gate connected to the differential output terminal XA, and a source connected to VSS. The transistor T5 has a drain connected to the differential output terminal XA, a gate connected to the differential output terminal XB, and a source connected to VSS.

FIG. 2 is a signal waveform diagram showing an operation example of the differential output circuit of FIG. 1. First, suppose
IN=L and INX=H.
   At this time,
XA=L and XB=H
   whereby the transistor T4 is OFF and the transistor T5 is ON in the adjusting circuit A1.

Assume that the signal transition timings of the differential input signals IN and INX are off from each other, and this causes INX to make an H to L transition before IN makes an L to H transition. At this time, the transistor T3 of the inverter INV2 turns ON, causing XA to start to rise. However, since the transistor T5 is ON, the rise of XA is restricted. Thereafter, when IN makes an L to H transition, the fall of XB is not restricted because the transistor T4 is OFF, allowing XB to make an H to L transition. With this, since the transistor T5 turns OFF, XA rises to H. As a result, the signal transition timings of the differential output signals XA and XB are synchronized.

Also, suppose
IN=H and INX=L.
   At this time,
XA=H and XB=L,
   whereby the transistor T4 is ON and the transistor T5 is OFF in the adjusting circuit A1.

Assume that the signal transition timings of the differential input signals IN and INX are off from each other, and this causes IN to make an H to L transition before INX makes an L to H transition. At this time, the transistor T2 of the inverter INV1 turns ON, causing XB to start to rise. However, since the transistor T4 is ON, the rise of XB is restricted. Thereafter, when INX makes an L to H transition, the fall of XA is not restricted because the transistor T5 is OFF, allowing XA to make an H to L transition. With this, since the transistor T4 turns OFF, XB rises to H. As a result, the signal transition timings of the differential output signals XA and XB are synchronized.

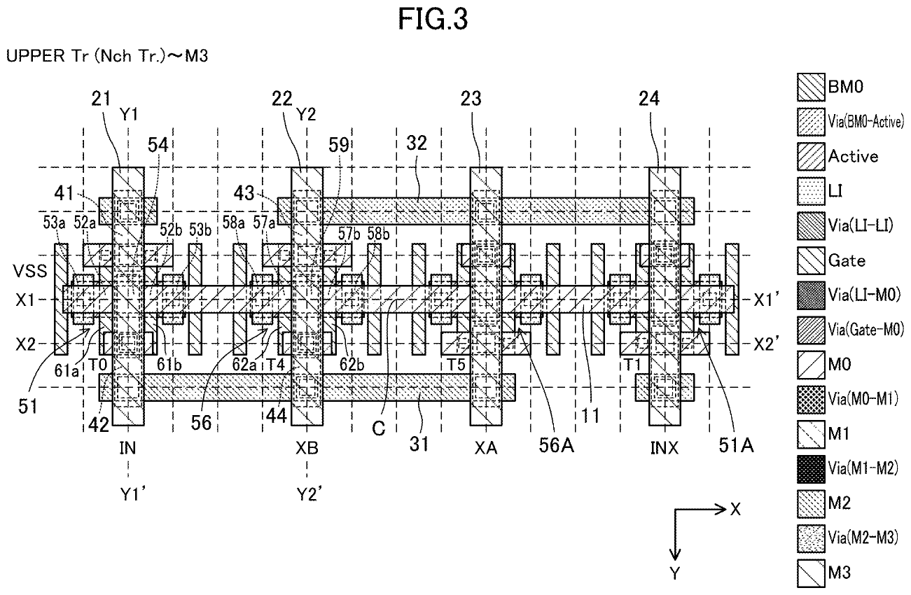

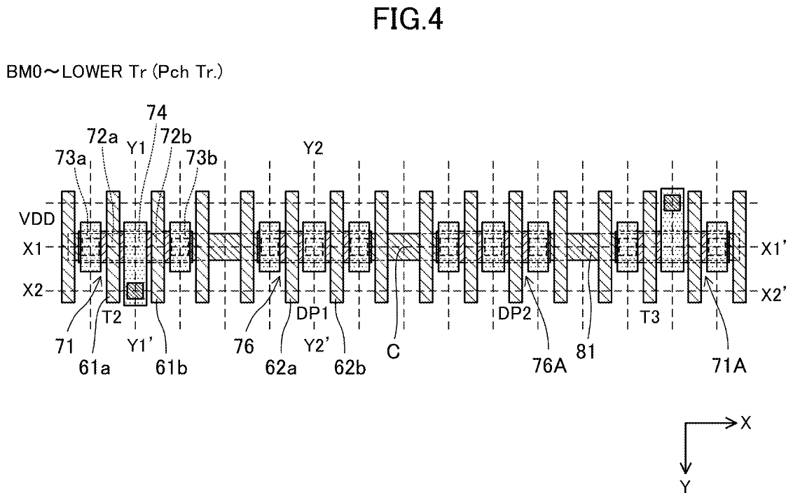

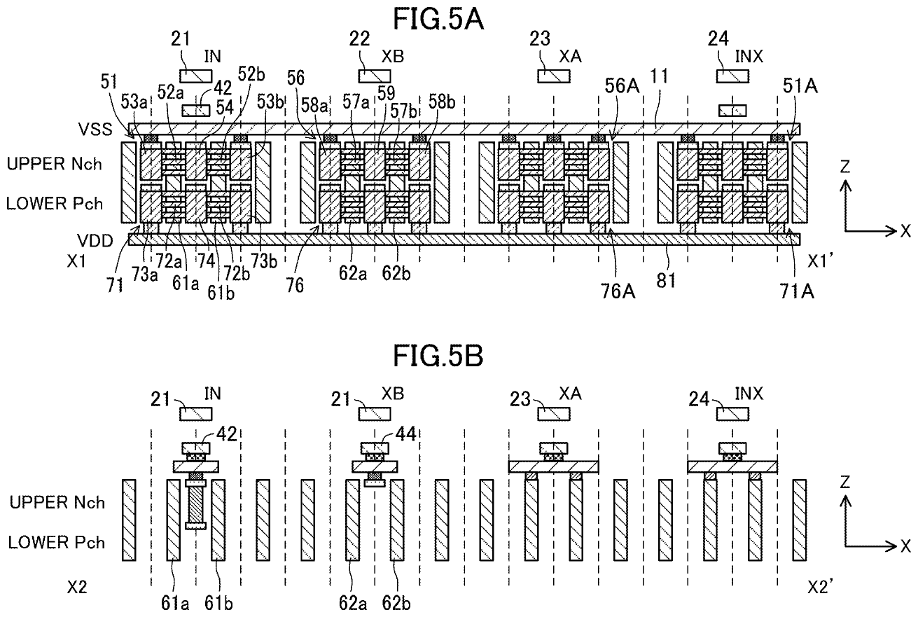

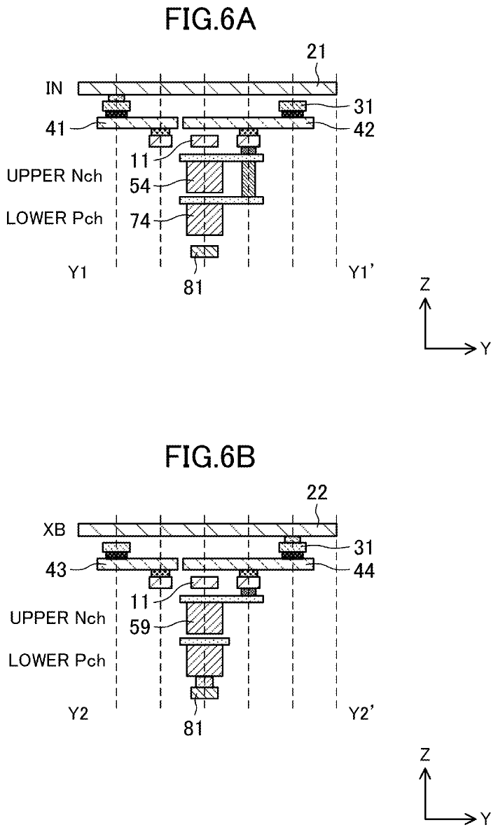

FIGS. 3 to 6B are views showing a layout structure example, using CFETs, of the differential output circuit of FIG. 1. Specifically, FIG. 3 is a plan view of an upper part that is a part including upper transistors formed at positions farther from the substrate, FIG. 4 is a plan view of a lower part that is a part including lower transistors formed at positions closer to the substrate, FIG. 5A is a cross-sectional view taken along line X1-X1′ in FIGS. 3 and 4, FIG. 5B is a cross-sectional view taken along line X2-X2′ in FIGS. 3 and 4, FIG. 6A is a cross-sectional view taken along line Y1-Y1′ in FIGS. 3 and 4, and FIG. 6B is a cross-sectional view taken along line Y2-Y2′ in FIGS. 3 and 4.

In this layout structure example, n-type nanosheet FETs are formed in the upper part, and p-type nanosheet FETs are formed in the lower part. The transistors T0, T1, T4, and T5 in the circuit diagram of FIG. 1 are formed in the upper part. In the lower part, the transistors T2 and T3 and dummy transistors DP1 and DP2 that are not illustrated in the circuit diagram of FIG. 1 are formed.

Note that, in the plan views such as FIG. 3, the horizontal direction in the figure is hereinafter referred to as an X direction, the vertical direction in the figure as a Y direction, and the direction normal to the substrate plane as a Z direction (corresponding to the depth direction). Also, hereinafter, the same components are denoted by the same reference characters, and description of such components may be omitted.

In FIG. 3, the transistors T0, T4, T5, and T1 are formed in this order from left in the figure. In FIG. 4, the transistor T2, the dummy transistors DP1 and DP2, and the transistor T3 are formed in this order from left in the figure. In FIGS. 3 and 4, each of the transistors T0 to T5 and the dummy transistors DP1 and DP2 is constituted by two parallel-connected transistors.

The planar layouts shown in FIGS. 3 and 4 are made point-symmetrically with respect to point C. That is, the planar layout of the transistors T0, T2, and T4 and the planar layout of the transistors T1, T3, and T5 are point-symmetric to each other.

The layout structure of the transistors T0, T2, and T4 will be mainly described hereinafter. As for the layout structure of the transistors T1, T3, and T5, description is omitted appropriately since this can be easily inferred by analogy from the description of the layout structure of the transistors T0, T2, and T4.

In an M0 layer, an interconnect 11 extending in the X direction is formed from the transistor T0 over to the transistor T1. The M0 layer is an interconnect layer located in the upper-face portion of the semiconductor chip. The interconnect 11 is a power line supplying VSS.

In an M3 layer, interconnects 21, 22, 23, and 24 extending in the Y direction are formed. The M3 layer is an interconnect layer located above the M0 layer. The interconnect 21 is placed above the transistor T0 and corresponds to the differential input terminal IN. The interconnect 22 is placed above the transistor T4 and corresponds to the differential output terminal XB. The interconnect 23 is placed above the transistor T5 and corresponds to the differential output terminal XA. The interconnect 24 is placed above the transistor T1 and corresponds to the differential input terminal INX.

In an M2 layer, interconnects 31 and 32 extending in the X direction are formed. The M2 layer is an interconnect layer located above the M0 layer and below the M3 layer. The interconnect 31 is placed on the lower side with respect to the M0 interconnect 11 in the figure to overlap the M3 interconnects 21, 22, and 23 in planar view. The interconnect 31 is connected to the M3 interconnect 22 through a via, but is not connected to the M3 interconnect 21 nor 23. The interconnect 32 is placed on the upper side with respect to the M0 interconnect 11 in the figure to overlap the M3 interconnects 22, 23, and 24 in planar view. The interconnect 32 is connected to the M3 interconnect 23 through a via, but is not connected to the M3 interconnect 22 nor 24.

In the region of the transistor T0, interconnects 41 and 42 extending in the Y direction are formed in an M1 layer. The M1 layer is an interconnect layer located above the M0 layer and below the M2 layer. The interconnects 41 and 42 are placed in a line and overlap the M3 interconnect 21 in planar view. The interconnect 41 is connected to the M3 interconnect 21 through a via, an M2 interconnect, and a via. The interconnect 42 is connected to the M2 interconnect 31 through a via. That is, the interconnect 41 is connected to the differential input terminal IN, and the interconnect 42 is connected to the differential output terminal XB.

In the region of the transistor T4, interconnects 43 and 44 extending in the Y direction are formed in the M1 layer. The interconnects 43 and 44 are placed in a line and overlap the M3 interconnect 22 in planar view. The interconnect 43 is connected to the M2 interconnect 32 through a via. The interconnect 44 is connected to the M3 interconnect 22 through a via, the M2 interconnect 31, and a via. That is, the interconnect 43 is connected to the differential output terminal XA, and the interconnect 44 is connected to the differential output terminal XB.

Below the M0 interconnect 11, formed are an active region 51 forming the channels, sources, and drains of n-type nanosheet FETs that are to be the transistor T0 and an active region 56 forming the channels, sources, and drains of n-type nanosheet FETs that are to be the transistor T4.

The active region 51 includes nanosheets 52a and 52b that are to be the channels of the n-type nanosheet FETs. In the active region 51, portions 53a and 53b that are to be the sources of the n-type nanosheet FETs are connected to the M0 interconnect 11 through local interconnects and vias. In the active region 51, also, a portion 54 that is to be the drains of the n-type nanosheet FETs is connected to the M1 interconnect 42 through a local interconnect, a via, an M0 interconnect, and a via.

Gate interconnects 61a and 61b extend in the Y direction and also extend in the Z direction from the upper part over to the lower part. The gate interconnects 61a and 61b surround the peripheries of the nanosheets 52a and 52b, respectively, in the Y direction and the Z direction through gate insulating films (not shown). The gate interconnects 61a and 61b are to be the gate of the transistor T0. The gate interconnects 61a and 61b are connected to the M1 interconnect 41 through vias, an M0 interconnect, and a via.

The active region 56 includes nanosheets 57a and 57b that are to be the channels of the n-type nanosheet FETs. In the active region 56, portions 58a and 58b that are to be the sources of the n-type nanosheet FETs are connected to the M0 interconnect 11 through local interconnects and vias. In the active region 56, also, a portion 59 that is to be the drains of the n-type nanosheet FETs is connected to the M1 interconnect 44 through a local interconnect, a via, an M0 interconnect, and a via.

Gate interconnects 62a and 62b extend in the Y direction and also extend in the Z direction from the upper part over to the lower part. The gate interconnects 62a and 62b surround the peripheries of the nanosheets 57a and 57b, respectively, in the Y direction and the Z direction through gate insulating films (not shown). The gate interconnects 62a and 62b are to be the gate of the transistor T4. The gate interconnects 62a and 62b are connected to the M1 interconnect 43 through vias, an M0 interconnect, and a via.

Note that the transistor T1 has an active region 51A forming the channels, sources, and drains of n-type nanosheet FETs, formed under the M0 interconnect 11. The transistor T5 has an active region 56A forming the channels, sources, and drains of n-type nanosheet FETs, formed under the M0 interconnect 11.

In FIG. 4, an active region 71 is formed at a position overlapping the active region 51 the transistor T0 in planar view. The active region 71 forms the channels, sources, drains of p-type nanosheet FETs that are to be the transistor T2. Also, an active region 76 is formed at a position overlapping the active region 56 of the transistor T4 in planar view. The active region 76 forms the channels, sources, drains of p-type nanosheet FETs that are to be the dummy transistor DP1.

In a BM0 layer, an interconnect 81 extending in the X direction is formed. The BM0 layer is an interconnect layer located in the backside portion of the semiconductor chip. The interconnect 81 is a power line supplying VDD.

The active region 71 includes nanosheets 72a and 72b that are to be the channels of p-type nanosheet FETs. In the active region 71, portions 73a and 73b that are to be the sources of the p-type nanosheet FETs are connected to the BM0 interconnect 81 through vias. In the active region 71, also, a portion 74 that is to be the drains of the p-type nanosheet FETs is connected to the M1 interconnect 42 through a local interconnect, a via, a local interconnect, a via, an M0 interconnect, and a via.

The gate interconnects 61a and 61b surround the peripheries of the nanosheets 72a and 72b, respectively, in the Y direction and the Z direction through gate insulating films (not shown).

Portions that are to be the sources and drains in the active region 76 are connected to t BM0 interconnect 81 through vias. The gate interconnects 62a and 62b surround the peripheries of the nanosheets in the active region 76 in the Y direction and the Z direction through gate insulating films (not shown).

Note that the transistor T3 has an active region 71A forming the channels, sources, and drains of p-type nanosheet FETS, formed at a position overlapping the active region 51A of the transistor T1 in planar view. The dummy transistor DP2 has an active region 76A forming the channels, sources, and drains of p-type nanosheet FETs, formed at a position overlapping the active region 56A of the transistor T5 in planar view.

The layout structure shown in FIGS. 3 to 6B has features as follows.

The layouts of the transistors T4 and T5 constituting the adjusting circuit A1 are made point-symmetrically with respect to the point C.

Specifically, the transistors T4 and T5 are each constituted by two transistors connected in parallel. Also, in the transistors T4 and T5, the gates, the sources, and the drains constituting the transistors are placed point-symmetrically and line-symmetrically to each other. The vias connected to the gates, the sources, and the drains are also placed point-symmetrically and line-symmetrically to each other. Also, the interconnects (local interconnects and M0 to M3 interconnects) connected to the transistors and the vias between the interconnects are placed point-symmetrically to each other.

Having the symmetric arrangement as described above, since unevenness in characteristics between the transistors T4 and T5 is curbed, a difference in signal transition timing between the differential output signals XA and XB is further curbed, in addition to the curb by the function of the adjusting circuit A1.

Also, the layouts of the transistors T0 and T2 constituting the inverter INV1 and the transistors T1 and T3 constituting the inverter INV2 are made point-symmetrically with respect to the point C. Therefore, a difference in signal transition timing between the differential output signals XA and XB is furthermore curbed.

The p-type dummy transistors DP1 and DP2 formed under the transistors T4 and T5 are also configured point-symmetrically and line-symmetrically to each other.

Specifically, the dummy transistors DP1 and DP2 are each constituted by two transistors each lying under the corresponding one of the two transistors constituting the transistor T4 or T5. The gates are formed integrally with the gates of the transistors T4 and T5 in the upper part, and therefore receive the same differential output signals XA and XB supplied to the transistors T4 and T5. The sources and the drains are all connected to the VDD-supply BM0 interconnect 81 through vias.

As described above, by configuring the dummy transistors DP1 and DP2 in the lower part, above which the transistors T4 and T5 are formed, symmetrically in layout, unevenness in the finished sizes of the transistors including the transistors T4 and T5 in the upper part is curbed.

Moreover, since the gates of the transistors T4 and T5 and the underlying dummy transistors DP1 and DP2 are integrally formed, not only the gates of the transistors T4 and T5 but also the gates of the dummy transistors DP1 and DP2 work as loads against the differential output signals XA and XB. In the above configuration, however, since the dummy transistors DP1 and DP2 are also configured symmetrically in layout, it is possible to curb unevenness in load against the differential output signals XA and XB.

As described above, according to this embodiment, a difference in signal transition timing between the differential output signals can be further curbed. That is, the semiconductor integrated circuit device according to this embodiment includes the transistors T4 and T5 constituting the adjusting circuit A1 that adjusts the signal transition timings of the differential output signals. The dummy transistors DP1 and DP2 are formed at positions different from the transistors T4 and T5 in the depth direction and overlapping these transistors in planar view. The active regions 56 and 56A of the transistors T4 and T5 are configured point-symmetrically and line-symmetrically to each other in planar view. The active regions 76 and 76A of the dummy transistors DP1 and DP2 are also configured point-symmetrically and line-symmetrically to each other. In the active regions 76 and 76A of the dummy transistors DP1 and DP2, the sources and the drains are all connected to the power supply VDD. With this configuration, since unevenness in the characteristics of the transistors T4 and T5 constituting the adjusting circuit A1 is curbed, it is possible to curb a difference in signal transition timing between the differential output signals.

### Alteration 1

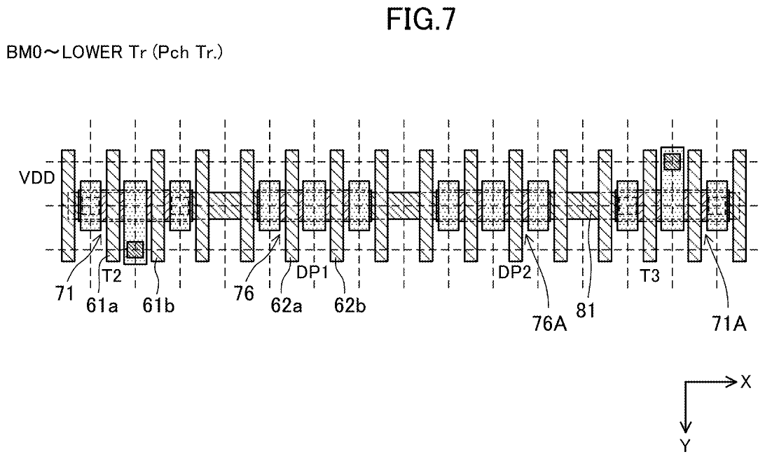

FIG. 7 is a view showing a layout structure according to Alteration 1 of the first embodiment, which is a plan view of the lower part including lower transistors. The layout structure of FIG. 7 is roughly the same as that of FIG. 4, except that the active regions 76 and 76A are not connected to the BM0 interconnect 81. That is, all of the sources and drains of the dummy transistors DP1 and DP2 are floating.

In this alteration, also, the dummy transistors DP1 and DP2 in the lower part, above which the transistors T4 and P5 are formed, are configured symmetrically in layout. Therefore, similar effects to those in the above embodiment can be obtained.

### Alteration 2

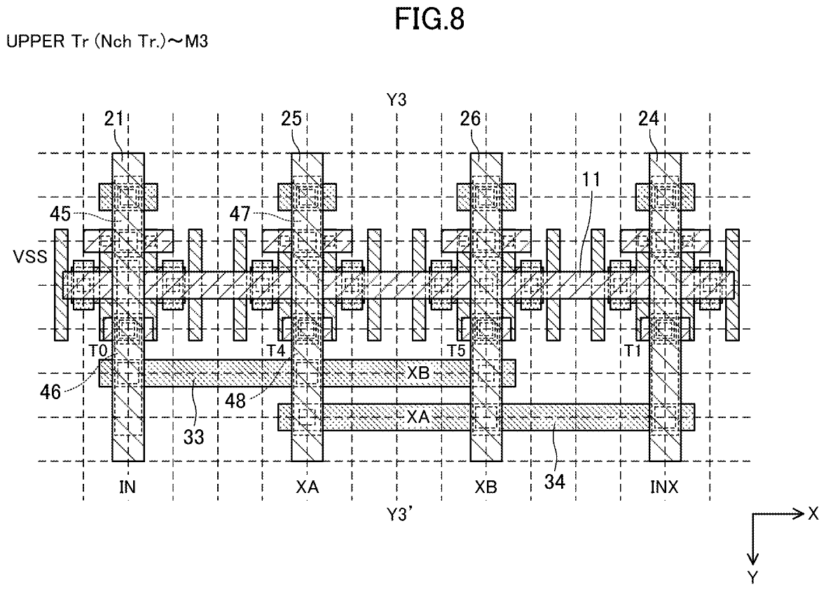

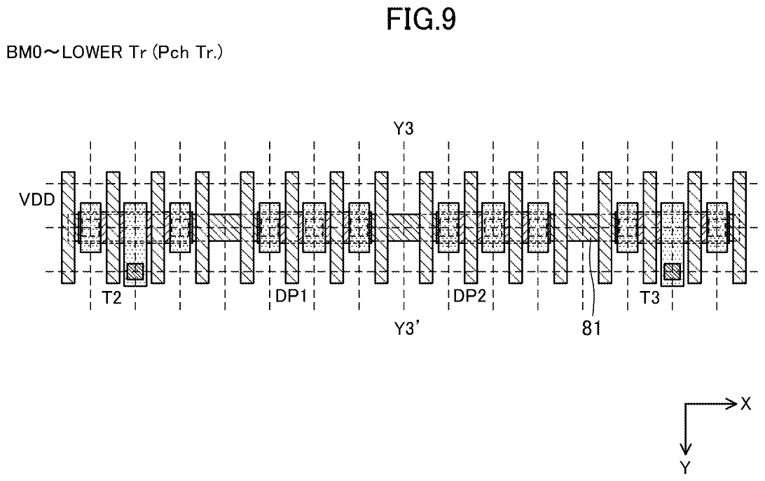

FIGS. 8 and 9 are views showing a layout structure according to Alteration 2 of the first embodiment, in which FIG. 8 is a plan view of an upper part and FIG. 9 is a plan view of a lower part. Illustration of cross-sectional structures of this alteration is omitted here.

In the first embodiment described above, the planar layouts shown in FIGS. 3 and 4 are made point-symmetrically. In Alteration 2, however, the planar layouts shown in FIGS. 8 and 9 are made line-symmetrically with respect to line Y 3-Y3′ as the symmetric axis. Note that, although the symmetry is broken in some of the M2 interconnects, at least the gates, sources, and drains of the transistors, the local interconnects, the M0 interconnects, and vias related to the M0 interconnects are configured line-symmetrically.

The planar layouts shown in FIGS. 8 and 9 will be described hereinafter mainly on points different from the planar layouts shown in FIGS. 3 and 4.

In FIG. 8, in the M3 layer, an interconnect 25 placed above the transistor T4 corresponds to the differential output terminal XA. An interconnect 26 placed above the transistor T5 corresponds to the differential output terminal XB.

In the M2 layer, interconnects 33 and 34 extending in the X direction are formed on the lower side with respect to the M0 interconnect 11 in the figure. The interconnect 33 is placed to overlap the M3 interconnects 21, 25, and 26 in planar view. The interconnect 33 is connected to the M3 interconnect 26 through a via, but is not connected to the M3 interconnect 21 nor 25. The interconnect 34 is placed to overlap the M3 interconnects 25, 26, and 24 in planar view. The interconnect 34 is connected to the M3 interconnect 25 through a via, but is not connected to the M3 interconnect 26 nor 24.

In the region of the transistor T0, interconnects 45 and 46 extending in the Y direction are formed in the M1 layer. The interconnects 45 and 46 are placed in a line and overlap the M3 interconnect 21 in planar view. The interconnect 45 is connected to the M3 interconnect 21 through a via, an M2 interconnect, and a via. The interconnect 46 is connected to the M2 interconnect 33 through a via. That is, the interconnect 45 is connected to the differential input terminal IN, and the interconnect 46 is connected to the differential output terminal XB.

In the region of the transistor T4, interconnects 47 and 48 extending in the Y direction are formed in the M1 layer. The interconnects 47 and 48 are placed in a line and overlap the M3 interconnect 25 in planar view. The interconnect 47 is connected to the M3 interconnect 25 through a via, an M2 interconnect, and a via. The interconnect 48 is connected to the M2 interconnect 33 through a via. That is, the interconnect 47 is connected to the differential output terminal XA, and the interconnect 48 is connected to the differential output terminal XB.

The planar layout of the transistors T1, T3, and T5 is line-symmetric to the planar layout of the transistors T0, T2, and T4.

In this alteration, similar effects as those in the above embodiment are obtained. That is, the layouts of the transistors T4 and T5 constituting the adjusting circuit A1 are made line-symmetrically with respect to the line Y3-Y3′ as the symmetric axis. Having the symmetric arrangement as described above, since unevenness in characteristics between the transistors T4 and T5 is curbed, a difference in signal transition timing between the differential output signals XA and XB is further curbed, in addition to the curb by the function of the adjusting circuit A1.

Also, the transistors T0 and T2 constituting the inverter INV1 and the transistors T1 and T3 constituting the inverter INV2 are configured line-symmetrically in layout with respect to the line Y3-Y3'. Therefore, a difference in signal transition timing between the differential output signals XA and XB is further curbed.

The p-type dummy transistors DP1 and DP2 formed under the transistors T4 and T5 are also configured line-symmetrically. Therefore, unevenness in finished size is curbed, and also unevenness in load against the differential output signals XA and XB can be curbed.

### Second Embodiment

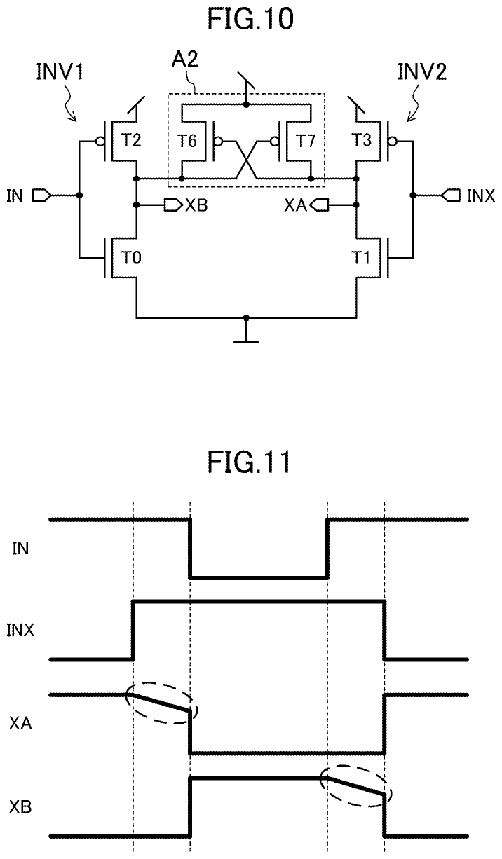

FIG. 10 is a circuit diagram showing a circuit configuration example of a differential output circuit according to the second embodiment. The differential output circuit of FIG. 10, like the differential output circuit of FIG. 1, receives differential input signals IN and INX as inputs, and outputs differential output signals XA and XB. The differential output circuit of FIG. 10 has a circuit (adjusting circuit A2) that adjusts the signal transition timings of the differential output signals XA and XB. The configurations of the inverters INV1 and INV2 are similar to those in the differential output circuit of FIG. 1.

P-type transistors T6 and T7 are cross-coupled between the differential output terminals XA and XB and constitute the adjusting circuit A2. That is, the transistor T6 has a drain connected to the differential output terminal XB, a gate connected to the differential output terminal XA, and a source connected to VDD. The transistor T7 has a drain connected to the differential output terminal XA, a gate connected to the differential output terminal XB, and a source connected to VDD.

FIG. 11 is a signal waveform diagram showing an operation example of the differential output circuit of FIG. 10. First, suppose
IN=H and INX=L.
   At this time,
XA=H and XB=L,
   whereby the transistor T6 is OFF and the transistor T7 is ON in the adjusting circuit A2.

Assume that the signal transition timings of the differential input signals IN and INX are off from each other, and this causes INX to make an L to H transition before IN makes an H to L transition. At this time, the transistor T1 of the inverter INV2 turns ON, causing XA to start to fall. However, since the transistor T7 is ON, the fall of XA is restricted. Thereafter, when IN makes an H to L transition, the rise of XB is not restricted because the transistor T6 is OFF, allowing XB to make an L to H transition. With this, since the transistor T7 turns OFF, XA falls to L. As a result, the signal transition timings of the differential output signals XA and XB are synchronized.

Also, suppose
IN=L and INX=H.
   At this time,
XA=L and XB=H,
   whereby the transistor T6 is ON and the transistor T7 is OFF in the adjusting circuit A2.

Assume that the signal transition timings of the differential input signals IN and INX are off from each other, causing IN to make an L to H transition before INX makes an H to L transition. At this time, the transistor T0 of the inverter INV1 turns ON, causing XB to start to fall. However, since the transistor T6 is ON, the fall of XB is restricted. Thereafter, when INX makes an H to L transition, the rise of XA is not restricted because the transistor T7 is OFF, allowing XA to make an L to H transition. With this, since the transistor T6 turns OFF, XB falls to L. As a result, the signal transition timings of the differential output signals XA and XB are synchronized.

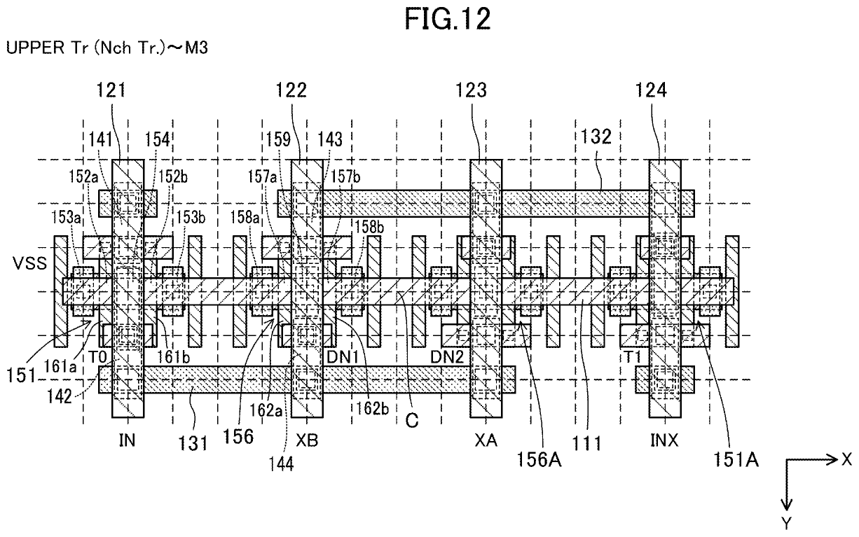

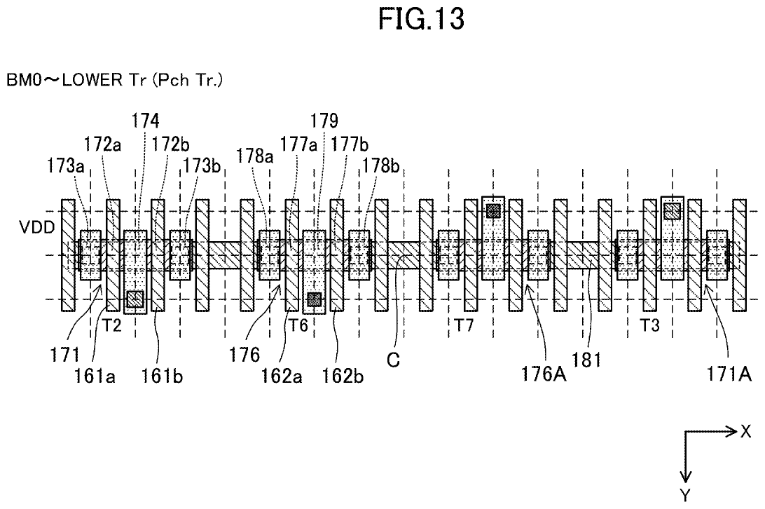

FIGS. 12 and 13 are views showing a layout structure example, using CFETs, of the differential output circuit of FIG. 10, in which FIG. 12 is a plan view of an upper part and FIG. 13 is a plan view of a lower part. In this layout structure example, as in the first embodiment, n-type nanosheet FETs are formed in the upper part, and p-type nanosheet FETs are formed in the lower part. Note that, as for the cross-sectional structures, illustration is omitted here since they can be easily inferred by analogy from the description in the first embodiment.

The transistors T0 and T1 in the circuit diagram of FIG. 10 are formed in the upper part, and the transistors T2, T3, T6, and T7 in the circuit diagram of FIG. 10 are formed in the lower part. Also, in the upper part, dummy transistors DN1 and DN2 that are not illustrated in the circuit diagram of FIG. 10 are formed at positions overlapping the transistors T6 and T7 in planar view.

In FIG. 12, the transistor T0, the dummy transistors DN1 and DN2, and the transistor T1 are formed in this order from left in the figure. In FIG. 13, the transistors T2, T6, T7, and T3 are formed in this order from left in the figure. In FIGS. 12 and 13, each of the transistors T0 to T3, T6, and T7 and the dummy transistors DN1 and DN2 is constituted by two parallel-connected transistors.

The planar layouts shown in FIGS. 12 and 13 are made point-symmetrically with respect to point C. That is, the planar layout of the transistors T0, T2, and T6 and the planar layout of the transistors T1, T3, and T7 are point-symmetric with respect to the point C.

The layout structure of the transistors T0, T2, and T6 will be mainly described hereinafter. As for the layout structure of the transistors T1, T3, and T7, description may be omitted appropriately since this can be easily inferred by analogy from the description of the layout structure of the transistors T0, T2, and T6.

In the M0 layer, an interconnect 111 extending in the X direction is formed from the transistor T0 over to the transistor T1. The interconnect 111 is a power line supplying VSS.

In the M3 layer, interconnects 121, 122, 123, and 124 extending in the Y direction are formed. The interconnect 121 is placed above the transistor T0 and corresponds to the differential input terminal IN. The interconnect 122 is placed above the dummy transistor DN1 and corresponds to the differential output terminal XB. The interconnect 123 is placed above the dummy transistor DN2 and corresponds to the differential output terminal XA. The interconnect 124 is placed above the transistor T1 and corresponds to the differential input terminal INX.

In the M2 layer, interconnects 131 and 132 extending in the X direction are formed. The interconnect 131 is placed on the lower side with respect to the M0 interconnect 111 in the figure to overlap the M3 interconnects 121, 122, and 123 in planar view. The interconnect 131 is connected to the M3 interconnect 122 through a via, but is not connected to the M3 interconnect 121 nor 123. The interconnect 132 is placed on the upper side with respect to the M0 interconnect 111 in the figure to overlap the M3 interconnects 122, 123, and 124 in planar view. The interconnect 132 is connected to the M3 interconnect 123 through a via, but is not connected to the M3 interconnect 122 nor 124.

In the region of the transistor T0, interconnects 141 and 142 extending in the Y direction are formed in the M1 layer. The interconnects 141 and 142 are placed in a line and overlap the M3 interconnect 121 in planar view. The interconnect 141 is connected to the M3 interconnect 121 through a via, an M2 interconnect, and a via. The interconnect 142 is connected to the M2 interconnect 131 through a via. That is, the interconnect 141 is connected to the differential input terminal IN, and the interconnect 142 is connected to the differential output terminal XB.

In the region of the dummy transistor DN1, interconnects 143 and 144 extending in the Y direction are formed in the M1 layer. The interconnects 143 and 144 are placed in a line and overlap the M3 interconnect 122 in planar view. The interconnect 143 is connected to the M2 interconnect 132 through a via. The interconnect 144 is connected to the M3 interconnect 122 through a via, an M2 interconnect, and a via. That is, the interconnect 143 is connected to the differential output terminal XA, and the interconnect 144 is connected to the differential output terminal XB.

Below the M0 interconnect 111, formed are an active region 151 forming the channels, sources, and drains of n-type nanosheet FETs that are to be the transistor T0 and an active region 156 forming the channels, sources, and drains of n-type nanosheet FETs that are to be the dummy transistor DN1.

The active region 151 includes nanosheets 152a and 152b that are to be the channels of the n-type nanosheet FETs. In the active region 151, portions 153a and 153b that are to be the sources of the n-type nanosheet FETs are connected to the M0 interconnect 111 through local interconnects and vias. In the active region 151, also, a portion 154 that is to be the drains of the n-type nanosheet FETs is connected to the M1 interconnect 142 through a local interconnect, a via, an M0 interconnect, and a via.

Gate interconnects 161a and 161b extend in the Y direction and also extend in the Z direction from the upper part over to the lower part. The gate interconnects 161a and 161b surround the peripheries of the nanosheets 152a and 152b, respectively, in the Y direction and the Z direction through gate insulating films (not shown). The gate interconnects 161a and 161b are to be the gate of the transistor T0. The gate interconnects 161a and 161b are connected to the M1 interconnect 141 through vias, an M0 interconnect, and a via.

The active region 156 includes nanosheets 157a and 157b that are to be the channels of the n-type nanosheet FETs. In the active region 156, portions 158a and 158b that are to be the sources of the n-type nanosheet FETs and a portion 159 that is to be the drains of the n-type nanosheet FETs are connected to the M0 interconnect 111 through local interconnects and vias.

Gate interconnects 162a and 162b extend in the Y direction and also extend in the Z direction from the upper part over to the lower part. The gate interconnects 162a and 162b surround the peripheries of the nanosheets 157a and 157b, respectively, in the Y direction and the Z direction through gate insulating films (not shown). The gate interconnects 162a and 162b are to be the gate of the dummy transistor DN1. The gate interconnects 162a and 162b are connected to the M1 interconnect 143 through vias, an M0 interconnect, and a via.

That is, the layout structure of the transistor T0 is similar to that of the transistor T0 described in the first embodiment. Also, the layout structure of the dummy transistor DN1 is roughly similar to that of the transistor T4 described in the first embodiment, but is different therefrom in that the portion 159 that is to be the drain is connected to the M0 interconnect 111.

Note that the transistor T1 has an active region 151A forming the channels, sources, and drains of n-type nanosheet FETs, formed under the M0 interconnect 111. The dummy transistor DN2 has an active region 156A forming the channels, sources, and drains of n-type nanosheet FETs, formed under the M0 interconnect 111.

In FIG. 13, an active region 171 is formed at a position overlapping the active region 151 of the transistor T0 in planar view. The active region 171 forms the channels, sources, drains of p-type nanosheet FETs that are to be the transistor T2. Also, an active region 176 is formed at a position overlapping the active region 156 of the dummy transistor DN1 in planar view. The active region 176 forms the channels, sources, drains of p-type nanosheet FETs that are to be the transistor T6.

In the BM0 layer, an interconnect 181 extending in the X direction is formed. The interconnect 181 is a power line supplying VDD.

The active region 171 includes nanosheets 172a and 172b that are to be the channels of p-type nanosheet FETs. In the active region 171, portions 173a and 173b that are to be the sources of the p-type nanosheet FETs are connected to the BM0 interconnect 181 through vias. In the active region 171, also, a portion 174 that is to be the drains of the p-type nanosheet FETs is connected to the M1 interconnect 142 through a local interconnect, a via, a local interconnect, a via, an M0 interconnect, and a via.

The gate interconnects 161a and 161b surround the peripheries of the nanosheets 172a and 172b, respectively, in the Y direction and the Z direction through gate insulating films (not shown).

The active region 176 includes nanosheets 177a and 177b that are to be the channels of p-type nanosheet FETs. In the active region 176, portions 178a and 178b that are to be the sources of the p-type nanosheet FETs are connected to the BM0 interconnect 181 through vias. In the active region 176, also, a portion 179 that is to be the drains of the p-type nanosheet FETs is connected to the M1 interconnect 144 through a local interconnect, a via, an M0 interconnect, and a via.

The gate interconnects 162a and 162b surround the peripheries of nanosheets 177aand 177b in the active region 176 in the Y direction and the Z direction through gate insulating films (not shown).

Note that the transistor T3 has an active region 171A forming the channels, sources, and drains of p-type nanosheet FETs, formed at a position overlapping the active region 151A of the transistor T1 in planar view. The transistor T7 has an active region 176A forming the channels, sources, and drains of p-type nanosheet FETs, formed at a position overlapping the active region 156A of the dummy transistor DN2 in planar view.

The layout structure shown in FIGS. 12 to 13 has features similar to those in the first embodiment. That is, the layouts of the transistors T6 and T7 constituting the adjusting circuit A2 are made point-symmetrically with respect to the point C. Specifically, the transistors T6 and T7 are each constituted by two transistors connected in parallel. Also, in the transistors T6 and T7, the gates, the sources, and the drains constituting the transistors are placed point-symmetrically and line-symmetrically to each other. The interconnects and the vias connected to the transistors are also placed point-symmetrically to each other.

Having the symmetric arrangement as described above, since unevenness in characteristics between the transistors T6 and T7 is curbed, a difference in signal transition timing between the differential output signals XA and XB is further curbed, in addition to the curb by the function of the adjusting circuit A2.

Also, the layouts of the transistors T0 and T2 constituting the inverter INV1 and the transistors T1 and T3 constituting the inverter INV2 are made point-symmetrically with respect to the point C. Therefore, a difference in signal transition timing between the differential output signals XA and XB is further curbed.

The n-type dummy transistors DN1 and DN2 formed above the transistors T6 and T7 are also configured point-symmetrically and line-symmetrically to each other.

Specifically, the dummy transistors DN1 and DN2 are each constituted by two transistors each lying above the corresponding one of the two transistors constituting the transistor T6 or T7. The gates are formed integrally with the gates of the transistors T6 and T7 in the lower part, and therefore receive the same differential output signals XA and XB supplied to the transistors T6 and T7. The sources and the drains are all connected to the VSS-supply M0 interconnect 111 through vias.

As described above, by configuring the dummy transistors DN1 and DN2 in the upper part, below which the transistors T6 and T7 are formed, symmetrically in layout, unevenness in the finished sizes of the transistors including the transistors T6 and T7 in the lower part is curbed.

Moreover, since the gates of the transistors T6 and T7 and the overlying dummy transistors DN1 and DN2 are integrally formed, not only the gates of the transistors T6 and T7 but also the gates of the dummy transistors DN1 and DN2 work as loads against the differential output signals XA and XB. In the above configuration, however, since the dummy transistors DN1 and DN2 are also configured symmetrically in layout, it is possible to curb unevenness in load against the differential output signals XA and XB.

As described above, according to this embodiment, a difference in signal transition timing between the differential output signals can be further curbed. That is, the semiconductor integrated circuit device according to this embodiment includes the transistors T6 and T7 constituting the adjusting circuit A2 that adjusts the signal transition timings of the differential output signals. The dummy transistors DN1 and DN2 are formed at positions different from the transistors T6 and T7 in the depth direction and overlapping these transistors in planar view. The active regions 176 and 176A of the transistors T6 and T7 are formed point-symmetrically and line-symmetrically to each other in planar view. The active regions 156 and 156A of the dummy transistors DN1 and DN2 are also formed point-symmetrically and line-symmetrically to each other. In the active regions 156 and 156A of the dummy transistors DN1 and DN2, the sources and the drains are all connected to the power supply VSS. With this configuration, since unevenness in the characteristics of the transistors T6 and T7 constituting the adjusting circuit A2 is curbed, it is possible to curb a difference in signal transition timing between the differential output signals.

Note that, as in Alteration 1 of the first embodiment, the active regions 156 and 156A constituting the dummy transistors DN1 and DN2 may be configured to have no connection to the M0 interconnect 111 supplying VSS. That is, all of the sources and drains of the dummy transistors DN1 and DN2 may be floating.

Also, as in Alteration 2 of the first embodiment, the layout structure may be made line-symmetric, not point-symmetric.

### Circuit Application Example 1

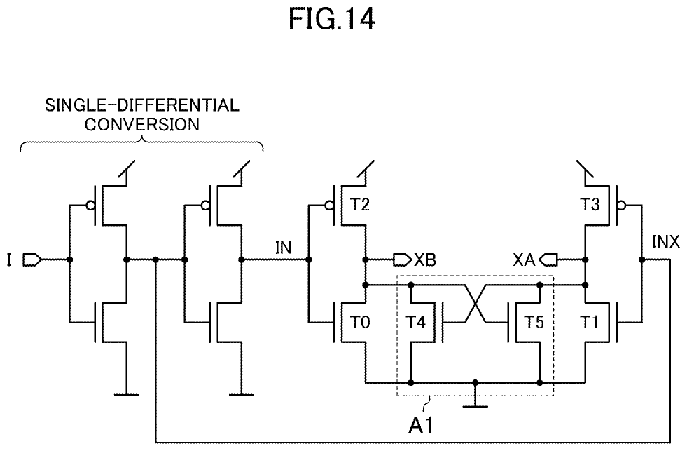

FIG. 14 shows an application example of the differential output circuits according to the embodiments described above. The circuit of FIG. 14 converts a single-end signal I into differential signals IN and INX via two inverters. The differential output circuits according to the embodiments are applied for these differential signals IN and INX. Note that, although the differential output circuit of the first embodiment is applied in FIG. 14, the differential output circuit of the second embodiment may also be applied.

In the circuit of FIG. 14, there is a delay difference equivalent of one inverter between the differential signals IN and INX. This difference in transition timing between the differential signals IN and INX is curbed by the adjusting circuit A1. In this case, by adopting the layout structures according to the above embodiments, effects as described above can be obtained.

### Circuit Application Example 2

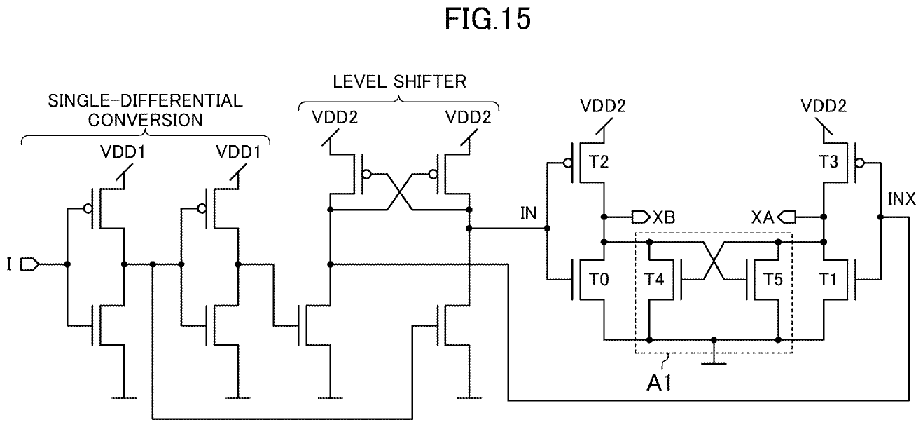

FIG. 15 shows an application example of the differential output circuits according to the embodiments described above. The circuit of FIG. 15 converts a single-end signal I having an amplitude VDD1 into differential signals via two inverters and further into differential signals IN and INX having an amplitude VDD2. The differential output circuits according to the embodiments are applied for these differential signals IN and INX. Note that, although the differential output circuit of the first embodiment is applied in FIG. 15, the differential output circuit of the second embodiment may also be applied.

In the circuit of FIG. 15, there is a delay difference equivalent of one inverter between the differential signals IN and INX. This difference in transition timing between the differential signals IN and INX is curbed by the adjusting circuit A1. In this case, by adopting the layout structures according to the above embodiments, effects as described above can be obtained.

### Other Embodiments

### (No. 1)

In the embodiments described above, the n-type nanosheet FETs are formed in the upper part and the p-type nanosheet FETs are formed in the lower part. However, the conductivity types may be reversed, to form p-type nanosheet FETs in the upper part and n-type nanosheet FETS in the lower part.

### (No. 2)

In the embodiments described above, all of the sources and drains of the dummy transistors overlapping the transistors constituting the adjusting circuit in planar view are connected to power supply, or are floating. However, the configuration is not limited to this. For example, all of the sources and drains of the dummy transistors may be connected to a predetermined node other than power supply.

Also, all of the sources and drains of the dummy transistors do not necessarily need to have the same electrical connection state. That is, according to the present disclosure, in the dummy transistors overlapping the transistors constituting the adjusting circuit in planar view, it is only necessary for sources and drains located at point-symmetric or line-symmetric positions to have the same electrical connection state. The electrical connection state as used herein may be any of the state connected to power supply, the floating state, and the state connected to a predetermined node other than power supply.

### (No. 3)

While the transistors constituting the differential output circuits are each made of two parallel-connected transistors in the embodiments described above, the configuration is not limited to this. That is, the transistors constituting the differential output circuits may be each made of one transistor or made of three or more transistors.

### (No. 4)

In the embodiments described above, the transistors that constituting the adjusting circuit and the dummy transistors overlapping these transistors in planar view have layout structures in which the active regions, the interconnects, and the vias are all point-symmetric or line-symmetric. Note however that the effects described in the embodiments can be obtained if only the active regions are point-symmetric or line-symmetric even if the interconnects and the vias are not point-symmetric or line-symmetric. Also, the effects will be more obtained if the local interconnects connected to the active regions are point-symmetric or line-symmetric, or the effects will be more obtained if the gates of the transistors are point-symmetric or line-symmetric. Moreover, a difference in signal transition timing between the differential output signals can be curbed more effectively if the interconnects and the vias connected to the transistors are point-symmetric or line-symmetric.

In the embodiments descried above, the nanosheet is illustrated to have a structure of three sheets lying one above another and having a rectangular cross-sectional shape. However, the number of sheets and cross-sectional shape of the sheet structure of the nanosheet are not limited to these.

While the transistors are nanosheet FETs in the embodiments described above, the configuration is not limited to this. For example, fin FETs or other types of transistors may be used.

According to the present disclosure, a difference in signal transition timing between differential output signals can be curbed more effectively. The present disclosure is therefore useful for improvement in the performance of a semiconductor integrated circuit device.

1. A semiconductor integrated circuit device, comprising:
a first transistor of a first conductivity type having a first active region forming a channel, source, and drain of a transistor;
a second transistor of the first conductivity type located at a same position as the first transistor in a depth direction and having a second active region forming a channel, source, and drain of a transistor;
a first dummy transistor of a second conductivity type located at a different position from the first transistor in the depth direction, placed at a position overlapping the first transistor in planar view, and having a third active region forming a channel, source, and drain of a transistor; and
a second dummy transistor of the second conductivity type located at a same position as the first dummy transistor in the depth direction, placed at a position overlapping the second transistor in planar view, and having a fourth active region forming a channel, source, and drain of a transistor,
wherein
the first transistor has a source connected to a power supply, a drain connected to a first node that is one of differential output terminals, and a gate connected to a second node that is the other of the differential output terminals,
the second transistor has a source connected to the power supply, a drain connected to the second node, and a gate connected to the first node,
the first dummy transistor has a gate connected to the second node,
the second dummy transistor has a gate connected to the first node,
the first active region and the second active region are configured line-symmetrically with respect to a predetermined straight line, or point-symmetrically with respect to a predetermined point, in planar view,
the third active region and the fourth active region are configured line-symmetrically with respect to the predetermined straight line, or point-symmetrically with respect to the predetermined point, in planar view, and
in the third and fourth active regions, electrical connection states of sources and drains located at symmetric positions with respect to the predetermined straight line, or located at symmetric positions with respect to the predetermined point, are the same.

2. The semiconductor integrated circuit device of claim 1, wherein
the electrical connection state is any of being connected to power supply, being floating, and being connected to a predetermined node other than power supply.

3. The semiconductor integrated circuit device of claim 1, wherein
the first transistor and the first dummy transistor are configured line-symmetrically to the second transistor and the second dummy transistor with respect to the predetermined straight line in planar view.

4. The semiconductor integrated circuit device of claim 1, wherein
the first transistor and the first dummy transistor are configured point-symmetrically t the second transistor and the second dummy transistor with respect to the predetermined point in planar view.

5. The semiconductor integrated circuit device of claim 1, further comprising:
a first inverter having third and fourth transistors and outputting an output signal to the first node; and
a second inverter having fifth and sixth transistors and outputting an output signal to the second node,
wherein
the third and fourth transistors and the fifth and sixth transistors are configured line-symmetrically with respect to the predetermined straight line, or point-symmetrically with respect to the predetermined point, in planar view.

6. The semiconductor integrated circuit device of claim 1, wherein
a local interconnect connected to the first active region and a local interconnect connected to the second active region are configured line-symmetrically with respect to the predetermined straight line, or point-symmetrically with respect to the predetermined point, in planar view, and
a local interconnect connected to the third active region and a local interconnect connected to the fourth active region are formed line-symmetrically with respect to the predetermined straight line, or point-symmetrically with respect to the predetermined point, in planar view.

7. The semiconductor integrated circuit device of claim 1, wherein
the gate of the first transistor and the gate of the second transistor are configured line-symmetrically with respect to the predetermined straight line, or point-symmetrically with respect to the predetermined point, in planar view, and
the gate of the first dummy transistor and the gate of the second dummy transistor are configured line-symmetrically with respect to the predetermined straight line, or point-symmetrically with respect to the predetermined point, in planar view.
